(19) United States
(12) Patent Application Publication
(10) Pub. No.: US 2006/0290238 A1
(43) Pub. Date: Dec. 28, 2006

(54) Electronic part having high sealing performance and method of manufacturing the same

(75) Inventor: Kyosuke Ozaki, Fukushima-ken (JP)

Correspondence Address: BEYER WEAVER & THOMAS, LLP, P.O. BOX 70250, OAKLAND, CA, 94612-0250, US

(73) Assignee: ALPS ELECTRIC CO., LTD.

(21) Appl. No.: 11/414,055

(22) Filed: Apr. 27, 2006

(30) Foreign Application Priority Data
Jun. 22, 2005 (JP) 2005-181372

(51) Int. Cl. H01L 41/053

(52) U.S. Cl. 310/340

(57) ABSTRACT

In order to increase sealing performance of an electronic part, a base substrate 11A on which a predetermined circuit pattern is formed, a mounting substrate 12A which faces the base surface 11A, an adhesive layer 17 which bonds the base substrate 11A with the mounting substrate 12A, and a sealing member 20 which seals the base substrate 11A and includes opened ends 21 and 21 therein. The opened ends are provided within a plate thickness of the mounting substrate 12A. It is possible to efficiently prevent leakage from being generated between the inside and the outside of the electronic part 10A and to improve the sealing performance of the electronic part 10A.

### BACKGROUND OF THE INVENTION

1. Field of the Invention

The present invention relates to an electronic part such as a surface acoustic wave (SAW) device and a method of manufacturing the same, and more particularly, to an electronic part having high sealing performance and a method of manufacturing the same.

2. Description of the Related Art

A surface acoustic wave device, which is a kind of a conventional electronic part, is connected in a flip chip fashion in a state that one surface of a piezoelectric substrate, on which a comb-like electrode is formed, and a base substrate face each other. In the surface acoustic wave device, the periphery of the piezoelectric substrate is covered by sealing resin except a hollow region in which the comb-like electrode is formed.

In the surface acoustic wave device of the electronic part, aluminum (Al) or Al alloy is generally used as a material of the comb-like electrode formed on the surface of the piezoelectric substrate. Since these electrode materials are apt to be influenced by moisture, high sealing performance of a SAW filter package is required.

However, in an electronic part (surface acoustic wave device) disclosed in Patent Document 1, sealing resin is bonded on a surface of a base substrate to perform sealing. Since the surface of the base substrate and a bonded surface of the sealing resin are on the same plane, leakage is apt to be generated. In addition, it is difficult to ensure high sealing performance.

### SUMMARY OF THE INVENTION

The present invention is to solve the conventional problems, and it is an object of the present invention to provide an electronic part having high sealing performance and a method of manufacturing the same, in an electronic part including a surface acoustic device.

According to the present invention, there is provided an electronic part having high sealing performance, including a base substrate on which a predetermined circuit pattern is formed; a mounting substrate which faces the base surface; an adhesive layer which bonds the base substrate with the mounting substrate; and a sealing member which seals the base substrate and includes opened ends therein, wherein the opened ends are provided within a plate thickness of the mounting substrate.

In the present invention, since the opened ends of the sealing member and the mounting substrate are not the same plane, it is possible to provide an electronic part having high sealing performance, in which leak is hardly generated.

For example, a step portion formed by thinning a portion of the mounting substrate in a plate thickness direction may be formed at an edge of the mounting substrate, and the opened ends may be provided within the step portion.

By this configuration, it is possible to increase sealing performance with a simple configuration.

In addition, an end of a bonded portion between the base substrate and the adhesive layer and an end of a bonded portion between the adhesive layer and the mounting substrate may be closely adhered to an inner wall of the sealing member.

By this configuration, it is possible to efficiently prevent leak from being generated through a bonded surface.

In addition, a metal layer may be provided between the base substrate and the sealing member.

Since the metal layer has sealing performance higher than that of resin, it is possible to provide an electronic part having excellent sealing performance.

In addition, the periphery of the sealing member may be covered by the metal layer. By this configuration, since double sealing can be performed, it is possible to provide an electronic part having excellent sealing performance.

For example, a piezoelectric substrate may be used as the base substrate and a comb-like electrode may be formed as the circuit pattern.

By this configuration, it is possible to provide a surface acoustic device having high sealing performance.

In addition, according to the present invention, there is provided a method of manufacturing an electronic part having high sealing performance, including a first step of forming a predetermined circuit pattern on a base substrate body having a wafer shape in each a device forming region; a second step of disposing a mounting substrate body having a wafer shape to face the base substrate body and bonding the substrate bodies to each other; a third step of cutting the base substrate body in a plate thickness direction and a portion of the mounting substrate body to form a first groove in each device forming region and dividing respective base substrates; a fourth step of integrally forming a sealing member made of resin on the divided base substrates; and a fifth step of cutting the mounting substrate body and the sealing member to divide respective electronic parts

By this invention, it is possible to surly form an electronic part having high sealing performance. In addition, since the electronic part can be integrally formed in a wafer state, it is possible to massively produce an electronic part having high sealing performance.

According to the present invention, there is a method of manufacturing an electronic part having high sealing performance, including a first step of forming a predetermined circuit pattern on a base substrate body having a wafer shape in each a device forming region; a second step of forming a second groove for defining the device forming region in one surface of a mounting substrate body having a wafer shape; a third step of disposing one surface of the mounting substrate body, in which the second groove is formed, and the base substrate body to face each other and bonding the substrate bodies to each other; a fourth step of cutting the base substrate body at a position facing the second groove to expose the second groove and dividing respective base substrates; a fifth step of integrally forming a sealing member made of resin on the periphery of each of the divided base substrates; and a sixth step of cutting the mounting substrate body and the sealing member to divide respective electronic parts.

By this invention, it is possible to surely form an electronic part having high sealing performance.

A step of integrally sealing the periphery of each of the divided base substrates with a metal layer may be included before forming the sealing member made of the resin.

By this configuration, it is possible to form an electronic part having excellent sealing performance by including the metal layer.

In addition, a step of integrally covering the periphery of the sealing member made of resin with a metal layer may be included after forming the sealing member made of the resin.

By this configuration, it is possible to form an electronic part having a double sealing structure.

A step of forming an additional sealing member made of resin on the periphery of the metal layer may be included.

Since a sealing structure can be multiplexed, it is possible to form an electronic part having higher sealing performance.

For example, the sealing member may be formed by curing molten resin inserted into the first groove or the second groove and the periphery of each of the divided base substrates.

By this configuration, it is possible to surely form a sealing member due to resin molding.

In addition, the sealing member may be formed by closely adhering a thermosetting resin sheet between the periphery of each of the base substrates and the first groove or the second groove.

By this configuration, it is possible to surely perform sealing with a simple configuration using a resin sheet.

In addition, the metal layer may be formed any one of a sputtering method, an electrolytic plating method, a nonelectrolytic plating method, and a deposition method, or a combination thereof.

By this configuration, it is possible to surely form a sealing member made of a metal layer.

In addition, a piezoelectric substrate may be used as the base substrate and a comb-like electrode may be formed as the circuit pattern.

By this configuration, it is possible to form a surface acoustic device having high sealing performance.

In the present invention, it is possible to provide an electronic part having excellent sealing performance. In addition, it is possible to provide a method of manufacturing an electronic part having excellent sealing performance

### BRIEF DESCRIPTION OF THE DRAWINGS

FIG. 1 is a cross-sectional view of a surface acoustic wave device as an electronic part according to a first embodiment of the present invention;

FIG. 2 is a process view showing a method of manufacturing the electrode part according to the first embodiment of the present invention;

FIG. 3 is a process view showing a modified example of FIG. 2;

FIG. 4 is a process view showing the method of manufacturing the electronic part after the steps of FIG. 2 or FIG. 3;

FIG. 5 is a cross-sectional view showing a surface acoustic wave device as an electronic part according to a second embodiment of the present invention;

FIG. 6 is a process view showing a method of manufacturing the electrode part according to the second embodiment of the present invention;

FIG. 7 is a cross-sectional view showing a surface acoustic wave device as an electronic part according to a third embodiment of the present invention;

FIG. 8 is a process view showing a method of manufacturing the electrode part according to the third embodiment of the present invention; and

FIG. 9 is a cross-sectional view showing a surface acoustic wave device as an electronic part according to a fourth embodiment of the present invention.

### DESCRIPTION OF THE PREFERRED EMBODIMENTS

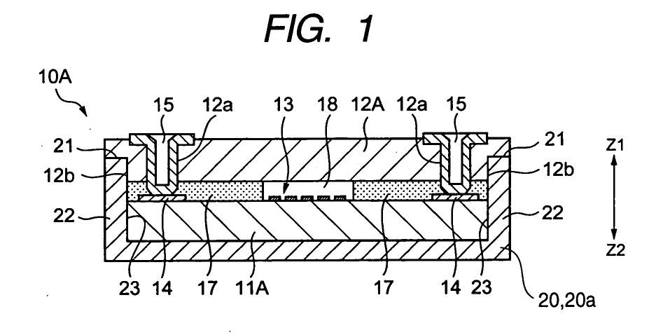

FIG. 1 is a cross-sectional view of a surface acoustic wave device as an electronic part according to a first embodiment of the present invention.

An electronic part 10A of the first embodiment shown in FIG. 1 includes a base substrate 11A and a mounting substrate 12A, which face each other at a predetermined distance. The base substrate 11A according to the present embodiment is made of a piezoelectric material. A circuit pattern including a pair of comb-like electrodes (inter-digital transducer (IDT) electrode) 13 made of a conductive material and terminal electrodes 14 and 14 continuously connected to ends of the comb-like electrodes 13 is formed on a surface (surface of a Z1 side) of the base substrate 11A.

Meanwhile, when an electronic part 10 is not a surface acoustic wave device, a circuit pattern including an electrode pattern made of a different conductive material or a dielectric film for a capacitor or a resistor film is formed.

Through-holes 12a and 12a are formed in a mounting substrate body 12 in a plate thickness direction (Z direction) and through-electrodes 15 and 15 formed using a method such as a sputtering method or a plating method is formed in the through-holes 12a and 12a. One ends (ends of the Z1 side) of the through-electrodes 15 and 15 are exposed to the surface 12A of the mounting substrate 12A and the other ends (ends of a Z2 side) thereof are connected to the surfaces of the terminal electrodes 14 and 14 which are the ends of the comb-like electrodes 13 formed on the base substrate 11A.

In a region in which the base substrate 11A and the mounting substrate 12A face each other, an adhesive layer 17 is disposed on a portion except a center portion in which the comb-like electrodes 13 is provided, and the base substrate 11A and the mounting substrate 12A are fixed to each other through the adhesive layer 17. Meanwhile, the center portion without the adhesive layer is a hollow region 18 for propagating a surface acoustic wave to the comb-like electrodes 13.

In addition, a sealing member 20 is sealed on the periphery of the base substrate 11A and the lower surface of the mounting substrate 12A. Meanwhile, in the electronic part 10A according to the first embodiment, the sealing member 20 is formed of a molded component made of resin and having an opened end at the Z1 side.

In the electronic part 10A, a step portion 12b is formed at an edge of the mounting substrate 12A within the plate thickness of the mounting substrate 12A, and opened ends 21 and 21 of the sealing member 20 are provided in the step portion 12b. In other words, the lower surface (surface of the Z2 side) of the base substrate 11A and the opened ends 21 and 21 of the sealing member 20 are not on the same plane. To this end, in the electronic part 10A, it is possible to prevent leak from being generated from a bonded surface between the base substrate 11A and the opened ends 21 and 21 of the sealing member 20.

In addition, an end of a bonded portion between the mounting substrate 12A and the adhesive layer 17 and an end of a bonded portion between the adhesive layer 17 and the base substrate 11A are within the height of a sidewall 22 for forming the opened ends 21 and 21 of the sealing member 20 and closely adhered to the inner surface 23 of the sealing member 20. To this end, it is possible to efficiently prevent the leak and provide the electronic part 10A having high sealing performance.

Hereinafter, a method of manufacturing the electronic part 11A will be described.

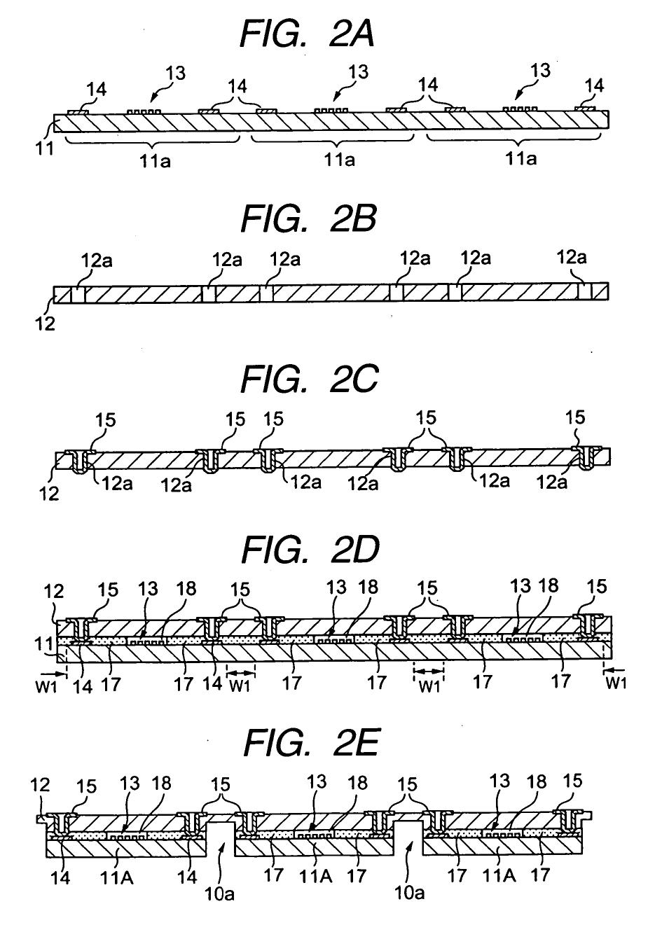

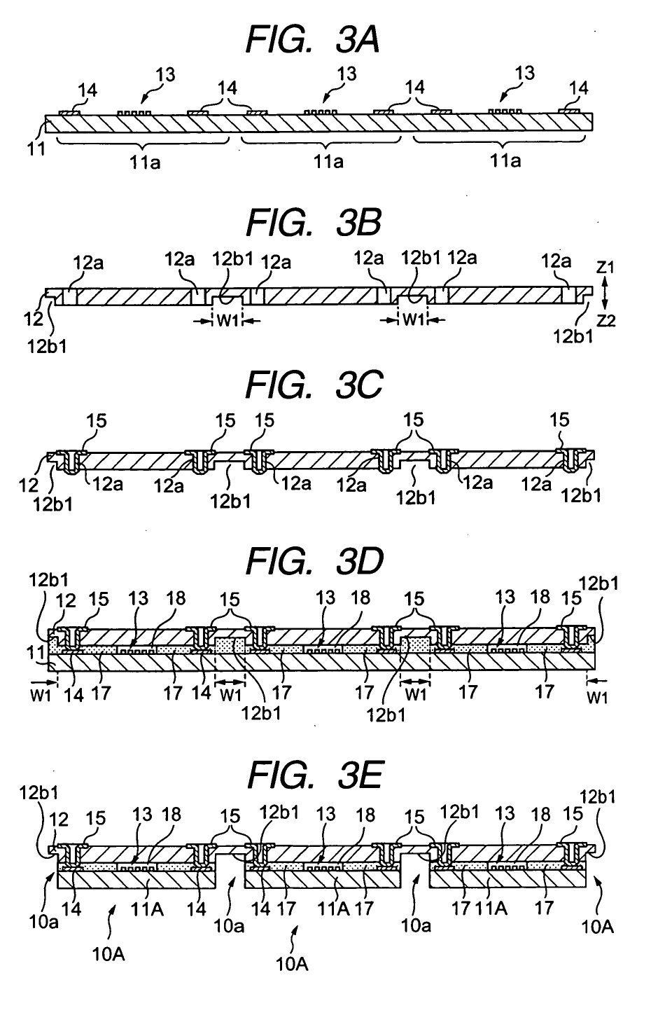

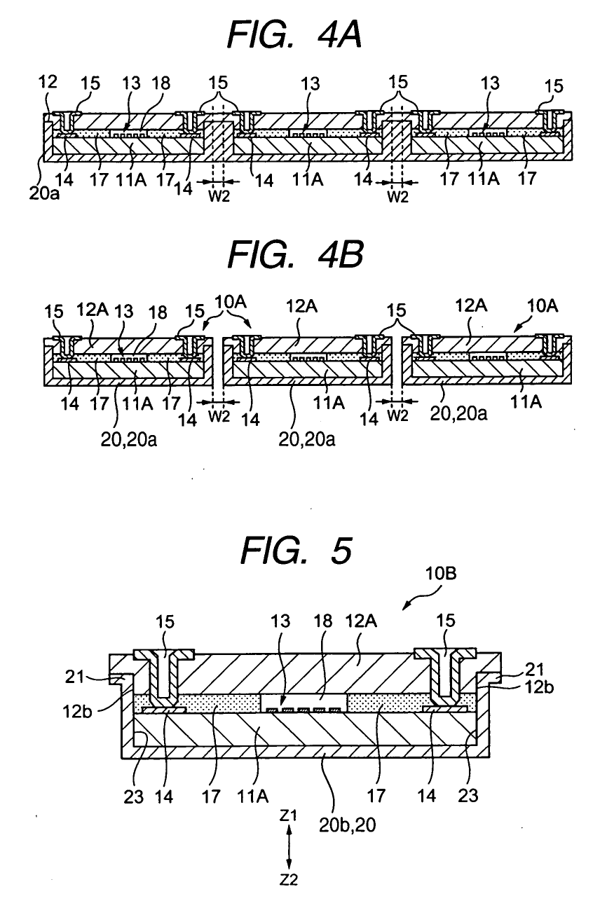

FIG. 2 is a process view showing a method of manufacturing the electrode part according to the first embodiment of the present invention, FIG. 3 is a process view showing a modified example of FIG. 2, and FIG. 4 is a process view showing the method of manufacturing the electronic part after the steps of FIG. 2 or FIG. 3. Meanwhile, FIGS. 2A to 2E and FIGS. 3A to 3E show the method of manufacturing the surface acoustic device and FIGS. 4A and 4B show a process of sealing the surface acoustic wave device.

First, the manufacturing method according to the first embodiment shown in FIGS. 2A to 2E will be described.

In a step shown in FIG. 2A, the base substrate body 11 having a wafer shape is prepared. A plurality of flat device forming regions 11a, 11a, . . . is formed on a surface (side of the Z1 side) of the base substrate body 11 and a predetermined circuit pattern including the comb-like electrode 13 (inter-digital transducer (IDT) electrode) or the terminal electrodes 14 and 14 is formed on each of the device forming regions 11a (first step).

Meanwhile, when the electronic part 10A formed by this manufacturing method is not the surface acoustic wave device, for example, the other circuit pattern such as a resistor film, a dielectric film for a capacitor, or an eddy pattern for a coil may be formed, instead of the comb-like electrode.

In a step shown in FIG. 2B, the mounting substrate body 12 having a wafer shape is prepared and the through-holes 12a and 12a are formed in the mounting substrate body 12 at positions corresponding to the terminal electrodes 14 and 14 formed in the device forming region 11a. Meanwhile, a mounting substrate body 12 having a wafer shape, in which through-holes 12a and 12a are previously formed, may be purchased or through-holes 12a and 12a may be formed in a mounting substrate body 12 after the mounting substrate body 12 having a wafer shape is purchased.

In a step shown in FIG. 2C, the through-electrodes 15 and 15 made of a conductive material, such as copper, silver, or gold, are formed in the through-holes 12a and 12a. The through-electrodes 15 and 15 may be formed by any one of a sputtering method, an electrolytic plating method and a nonelectrolytic plating method, or a combination thereof.

In a step shown in FIG. 2D, an adhesive layer 17 is provided on the base substrate body 11 having the wafer shape, which is formed in FIG. 2A, and the mounting substrate body 12 having the wafer shape, which is formed in FIG. 2B, is loaded thereon, thereby bonding the base substrate body 11 and the mounting substrate body 12 to each other (second step).

The adhesive layer 17 is provided on a region except a center portion in each device forming region 11a, on which the comb-like electrode 13 is formed. Accordingly, when the base substrate body 11 and the mounting substrate body 12 are bonded to each-other through the adhesive layer 17, the hollow region 18 by which the comb-like electrode 13 is exposed is formed in the center portion of the device forming region 11a. By the hollow region 18, it is possible to propagate a surface acoustic wave to the comb-like electrode 13.

In a step shown in FIG. 2E, the base substrate body 11 and a portion of the mounting substrate body 12 are cut between the device forming region 11a and the device forming region 11a, which are adjacent to each other, with a predetermined cut width W1 (third step). At this time, the base substrate body 11 and the adhesive layer 17 are wholly cut in a plate thickness direction, but the mounting substrate body 12 is partially cut such that a portion thereof remains in the plate thickness direction in a state that a first groove 10a having a cross-sectional concave portion is formed.

Meanwhile, even after the base substrate body 11 is cut, the electronic parts 10 are connected to one another through the mounting substrate body 12. To this end, the electronic parts 10 are not divided.

As a cutting method in the step of FIG. 2E, various methods such as a dicing process, a laser process, a milling process using an end mill, a dry etching method, and a wet etching method may be used.

Next, a manufacturing method using a modified example of the first embodiment shown in FIGS. 3A to 3E will be described. Meanwhile, the modified example shown in FIGS. 3A to 3E is substituted for the first embodiment shown in FIGS. 2A to 2E.

A step shown in FIG. 3A is similar to that shown FIG. 2A. In other words, on each of flat device forming regions 11a, 11a, . . . formed on the base substrate body 11 having the wafer shape, a predetermined circuit pattern including the comb-like electrode 13 (inter-digital transducer (IDT) electrode) or the terminal electrodes 14 and 14 is formed (first step)

A step shown in FIG. 3B corresponds to the step shown in FIG. 2B. In other words, the through-holes 12a and 12a are formed in the prepared mounting substrate body 12 at positions corresponding to the terminal electrodes 14 and 14. By thinning a portion of the mounting substrate body 12 at the lower surface (surface of the Z2 side) of the mounting substrate body 12 between the through-hole 12a and the through-hole 12a, a second groove 12b1 is formed with the same width (see FIG. 2D) as the cut width W1. Meanwhile, the second groove 12b1 forms a portion of the step portion 12b.

A step shown in FIG. 3C is similar to that shown in FIG. 2C. In other words, the through-electrodes 15 and 15 made of the conductive material such as copper, silver, or gold are formed in the through-holes 12a and 12a formed in the previous step, for example, using a sputtering method.

In a step shown in FIG. 3D, the adhesive layer 17 is provided on the base substrate body 11 having the wafer shape, which is formed in FIG. 2A, the mounting substrate body 12 having the wafer shape is loaded thereon, and the base substrate body 11 and the mounting substrate body 12 are bonded to each other through the adhesive layer 17 (second step). Meanwhile, in this case, a hollow region 18 by which the comb-like electrode 13 is exposed is formed in the center portion of the device forming region 11a.

In a step shown in FIG. 3E, the base substrate body 11 and the adhesive layer 17 located at a portion corresponding to the second groove 12b1 are cut with the cut width W1 to form a first groove 10a.

At this time, the base substrate body 11 and the adhesive layer 17 are wholly cut in a plate thickness direction, but the mounting substrate body 12 is partially cut such that the second groove 12b1 remains in the plate thickness direction. Meanwhile, even in this case, since the respective base substrates 11A are connected to one another through the mounting substrate body 12, the electronic parts 10 are not separated.

Next, a method of sealing the electronic part will be described with reference to FIGS. 4A and 4B. FIG. 4 shows the subsequent steps of FIG. 2 or FIG. 3.

In a step shown in FIG. 4A, a liquid resin material 20a such as epoxy or polyimide is filled on the periphery of the individually cut base substrate 11A and on a lower surface of the mounting substrate body 12 such that the periphery of the base substrate 11A is integrally closed and sealed by a sealing member 20 made of the resin material 20a (fifth step).

As a method of filling the resin material 20a, for example, various methods such as a transfer molding method or an insert molding method of mounting the lower side (base substrate 11A) of the mounting substrate body 12 in a mold cavity and inserting the molten resin material 20a into the heated mold cavity may be used.

In a step shown in FIG. 4B, the mounting substrate body 12 and the resin material 20a after curing are divided by the above-described dicing process in a unit of the device forming region 11a (sixth step). At this time, when the cut width W2 of the step shown in FIG. 3B is narrower than the cut width W1 of the step shown in FIG. 2E (W1>W2), it is possible to prevent a portion of the base substrate 11A or a portion of the adhesive layer 17 from being exposed from the sealing member 20. In other words, it is possible to completely seal the electronic part 10A by the sealing member 20 and the mounting substrate 12A mounted thereon. Accordingly, since the circuit pattern (comb-like electrode 13 and the terminal electrode 14) provided in the hollow region 18 can be blocked from the outside (external air), it is possible to provide the electronic part 10A having excellent sealing performance.

In addition, in the manufacturing method according to the first embodiment shown in FIGS. 2 and 3, the circuit patterns can be integrally formed before the wafer is not divided into the respective electronic parts 10A. Furthermore, even in the manufacturing method shown in FIG. 4, the respective electronic parts 10A can be simultaneously sealed in the wafer state. Accordingly, it is possible to significantly improve production efficiency, compared with the conventional method.

Next, an electronic part and a method of manufacturing the same according to a second embodiment of the present invention will be described.

FIG. 5 is a cross-sectional view showing a surface acoustic wave device as the electronic part according to the second embodiment of the present invention.

An electrode part 10B shown in FIG. 5 has the substantially same configuration as the electronic part 10A according to the first embodiment. In the electronic part 10A according to the first embodiment, the base substrate 11A is sealed by the sealing member 20 made of a resin molded component, whereas, in the electronic part 10B according to the second embodiment, the base substrate is sealed by a sealing member 20 made of a resin sheet.

Meanwhile, as shown in FIG. 5, the electronic part 10B according to the second embodiment is similar to the first embodiment in that the step portions 12b and 12b are formed in the edges of the mounting substrate 12A and the opened ends 21 and 21 of the sealing member 20 made of the resin sheet are provided in the step portions 12b and 12b.

To this end, even in the electronic part 10B, it is possible to prevent leak from being generated from the bonded surfaces between the base substrate 11A and the opened ends 21 and 21 of the sealing member 20, similar to above. In addition, an end of a bonded portion between the mounting substrate 12A and the adhesive layer 17 and an end of a bonded portion between the adhesive layer 17 and the base substrate 11A are within the height of a sidewall 22 for forming the opened ends 21 and 21 of the sealing member 20 and closely adhered to an inner surface 23 of the sealing member 20. To this end, it is possible to efficiently prevent the leak and to provide the electronic part 10B having high sealing performance.

A method of manufacturing the electronic part 10B will be described.

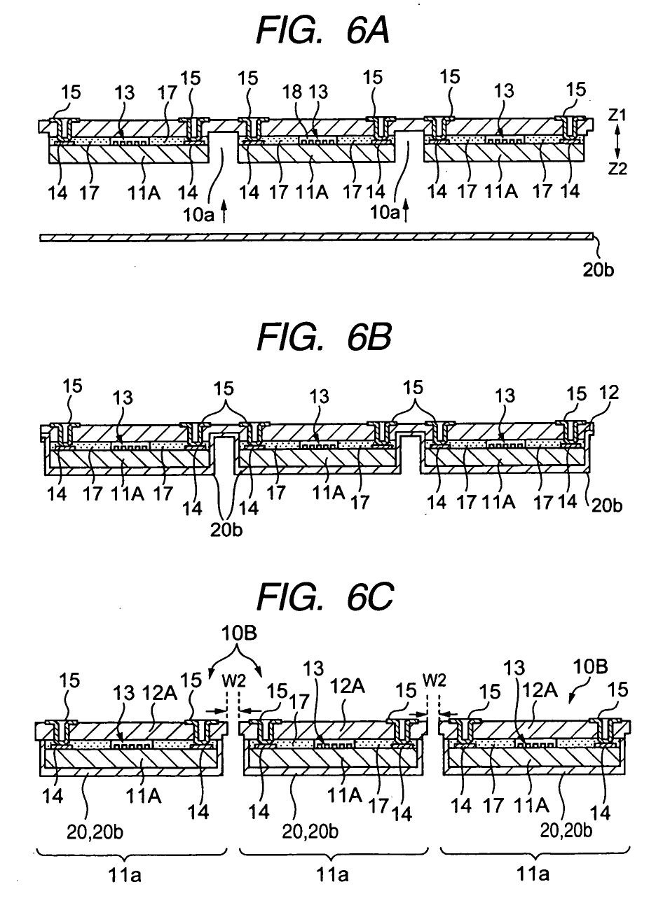

FIG. 6 is a process view showing a method of manufacturing the electrode part according to the second embodiment of the present invention. A step shown in FIG. 6A shows a subsequent step of FIG. 2E or 3E.

In the step shown in FIG. 6A, a thermosetting resin sheet 20b is disposed at a lower side (Z2) of the respective base substrates 11A formed in the step of FIG. 2E or 3E.

In a step shown in FIG. 6B, a resin sheet 20b is closely adhered to the base substrate 11A using a method such as compression pneumatic molding (also referred to as “pneumatic molding” or “pressure molding”). By lengthening and deforming the heated and softened resin sheet 20b with compressed air to have the same shape as that of the base substrate 11A, the resin sheet 20b is integrally adhered to the respective base substrates 11A (fourth step).

In addition, as shown in FIG. 6C, after the resin sheet 20b is cured, the mounting substrate body 12 is cut between the device forming region 11a and the device forming region 11a, which are adjacent to each other, with a cut width W2 narrower than the cut width W1 (W1>W2), the respective electronic parts 10B are separated from the mounting substrate body 12 (fifth step). In this embodiment, the individually cut resin sheet 20b can function as the sealing member 20 covering the base substrate 11A.

Next, an electronic part and a method of manufacturing according to a third embodiment of the present invention will be described.

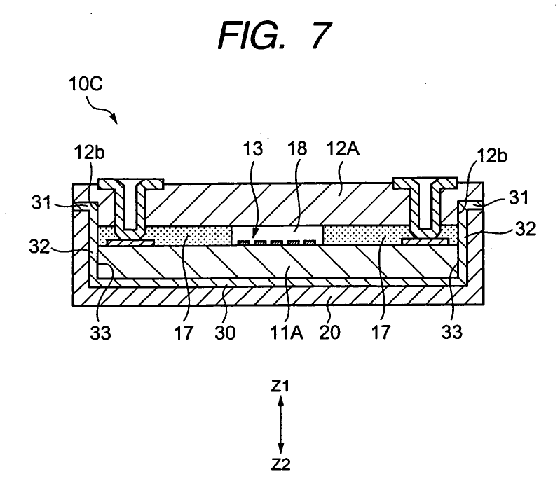

FIG. 7 is a cross-sectional view showing a surface acoustic wave device as the electronic part according to the third embodiment of the present invention.

An electronic part 10C shown in FIG. 7 is similar to the electronic part 11A or 10B, except that a metal layer 30 is provided between the base substrate 11A and the sealing member 20 made of resin and the

In the electronic part 10C, the base substrate 11A can be doubly sealed by the metal layer 30 provided at the outside of the base substrate 11A and the sealing member 20 made of resin and provided at the outside of the metal layer 30. The metal layer 30 functions as the sealing member.

In addition, opened ends 31 and 31 of the metal layer 30 are provided in the step portion 12b and 12b of the mounting substrate 12A to be positioned within the plate thickness of the mounting substrate 12A. To this end, similar to above, it is possible to prevent leak from being generated from bonded surfaces of the opened ends 31 and 31 of the metal layer 30 and the base substrate 11A.

In addition, an end of a bonded portion between the mounting substrate 12A and the adhesive layer 17 and an end of a bonded portion between the adhesive layer 17 and the base substrate 11A are within the height of a sidewall 32 for forming the metal layer 30 and closely adhered to an inner surface 33 of the metal layer 30. To this end, similar to above, it is possible to efficiently prevent the leak and to provide the electronic part 10C having high sealing performance.

A method of manufacturing the electronic part 10C will be described.

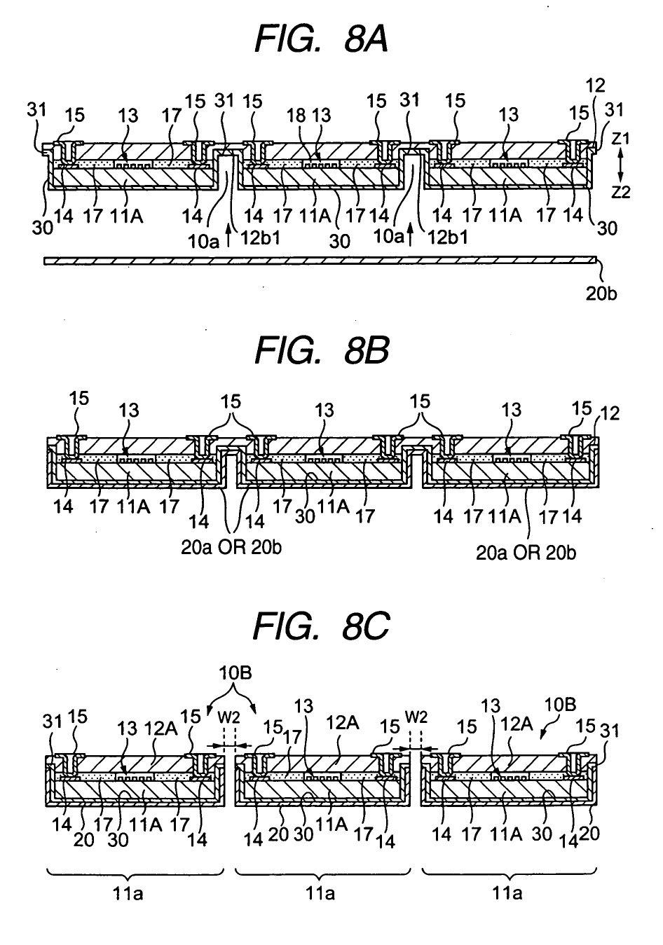

FIG. 8 is a process view showing a method of manufacturing the electrode part according to the third embodiment of the present invention. A step shown in FIG. 8A shows a subsequent step of FIG. 2E or 3E.

In a step shown in FIG. 8A, the respective base substrates 11A, which are formed in the step shown in FIG. 2E or 3E, are subjected to any one of a sputtering method, an electrolytic plating method and a deposition method, or a combination thereof to cover the base substrate 11A with the metal layer 30. At this time, the metal layer 30 is laminated in the second groove 12b1 and the opened end 31 for forming the step portion 12b is formed.

In a step shown in FIG. 8B, the periphery of the metal layer 30 is covered by the sealing member 20. The sealing member 20 may seal the periphery of the metal layer 30 with the resin material 20a using the transfer molding method or the insert molding method or seal the periphery of the metal layer 30 with the resin sheet 20b using the compression air pressure molding method.

In a step shown in FIG. 8C, by cutting the mounting substrate body 20 between the device forming region 11a and the device forming region 11a, which are adjacent to each other, with the cut width W2 narrower than the cut width W1 (W1>W2), the respective electronic parts 10C is separated from the mounting substrate body 12.

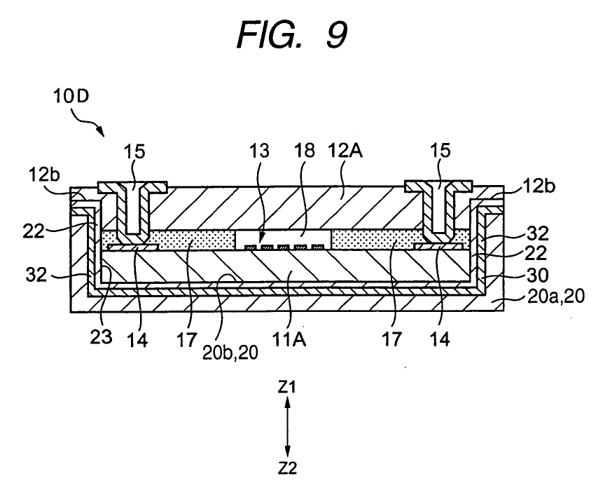

FIG. 9 is a cross-sectional view showing a surface acoustic wave device as an electronic part according to a fourth embodiment of the present invention.

An electronic part 10D according to the fourth embodiment is similar to the above-described embodiments except that a resin sheet 20b is formed on the periphery of the base substrate 11A outward as a first layer, the metal layer 30 is formed at the outside thereof as a second layer, and a resin material 20a at the outside thereof a third layer.

In addition, the electronic part 10D can be formed by using the same means as that described above, that is, covering the periphery of the base substrate 11A with the resin sheet 20b, forming the metal layer 30 on the periphery of the resin sheet 20b using any one of the sputtering method, the electrolytic plating method, or the deposition method or a combination thereof, and sealing the metal layer 30 with the resin material 20a using the transfer molding method or the insert molding method.

By alternately forming a resin material and a metal material, or laminating a resin material or a metal material on a resin material, that is, doubly or trebly laminating various materials, it is possible to more improve the sealing performance.

Although, in the embodiments, a surface acoustic device is described as an example of an electronic part, the present invention is not limited to the embodiments. The present invention is applicable to any electronic part which requires sealing.

What is claimed is:

1. An electronic part having high sealing performance, comprising:
a base substrate on which a predetermined circuit pattern is formed;
a mounting substrate which faces the base surface;
an adhesive layer which bonds the base substrate with the mounting substrate; and
a sealing member which seals the base substrate and includes opened ends therein,
wherein the opened ends are provided within a plate thickness of the mounting substrate.

2. The electronic part having high sealing performance according claim 1, wherein a step portion formed by thinning a portion of the mounting substrate in a plate thickness direction is formed at an edge of the mounting substrate, and the opened ends are provided within the step portion.

3. The electronic part having high sealing performance according claim 1, wherein an end of a bonded portion between the base substrate and the adhesive layer and an end of a bonded portion between the adhesive layer and the mounting substrate are closely adhered to an inner wall of the sealing member.

4. The electronic part having high sealing performance according claim 1, wherein a metal layer is provided between the base substrate and the sealing member.

5. The electronic part having high sealing performance according claim 1, wherein the periphery of the sealing member is covered by the metal layer.

6. The electronic part having high sealing performance according claim 1, wherein a piezoelectric substrate is used as the base substrate and a comb-like electrode is formed as the circuit pattern.

7. A method of manufacturing an electronic part having high sealing performance, comprising:
a first step of forming a predetermined circuit pattern on a base substrate body having a wafer shape in each a device forming region;
a second step of disposing a mounting substrate body having a wafer shape to face the base substrate body and bonding the substrate bodies to each other;
a third step of cutting the base substrate body in a plate thickness direction and a portion of the mounting substrate body to form a first groove in each device forming region and dividing respective base substrates;
a fourth step of integrally forming a sealing member made of resin on the divided base substrates; and
a fifth step of cutting the mounting substrate body and the sealing member to divide respective electronic parts.

8. A method of manufacturing an electronic part having high sealing performance, comprising:
a first step of forming a predetermined circuit pattern on a base substrate body having a wafer shape in each a device forming region;
a second step of forming a second groove for defining the device forming region in one surface of a mounting substrate body having a wafer shape;
a third step of disposing one surface of the mounting substrate body, in which the second groove is formed, and the base substrate body to face each other and bonding the substrate bodies to each other;
a fourth step of cutting the base substrate body at a position facing the second groove to expose the second groove and dividing respective base substrates;
a fifth step of integrally forming a sealing member made of resin on the periphery of each of the divided base substrates; and
a sixth step of cutting the mounting substrate body and the sealing member to divide respective electronic parts.

9. The method of manufacturing an electronic part having high sealing performance according to claim 7, further comprising a step of integrally sealing the periphery of each of the divided base substrates with a metal layer before forming the sealing member made of the resin.

10. The method of manufacturing an electronic part having high sealing performance according to claim 7, further comprising a step of integrally covering the periphery of the sealing member made of resin with a metal layer after forming the sealing member made of the resin.

11. The method of manufacturing an electronic part having high sealing performance according to claim 10, further comprising a step of forming an additional sealing member made of resin on the periphery of the metal layer.

12. The method of manufacturing an electronic part having high sealing performance according to claim 7, wherein the sealing member is formed by curing molten resin inserted into the first groove or the second groove and the periphery of each of the divided base substrates.

13. The method of manufacturing an electronic part having high sealing performance according to claim 7, wherein the sealing member is formed by closely adhering a thermosetting resin sheet between the periphery of each of the base substrates and the first groove or the second groove.

14. The method of manufacturing an electronic part having high sealing performance according to claim 9, wherein the metal layer is formed any one of a sputtering method, an electrolytic plating method, a nonelectrolytic plating method, and a deposition method, and a combination thereof.

15. The method of manufacturing an electronic part having high sealing performance according to claim 9, wherein a piezoelectric substrate is used as the base substrate and a comb-like electrode is formed as the circuit pattern.
